(19) United States
(12) Patent Application Publication
(10) Pub. No.: US 2026/0143664 A1
(43) Pub. Date: May 21, 2026

(54) MEMORY DEVICE HAVING HIGH PERFORMANCE

(71) Applicant: TAIWAN SEMICONDUCTOR MANUFACTURING COMPANY, LTD., Hsinchu (TW)

(72) Inventor: Jhon Jhy LIAW, Hsinchu (TW)

(73) Assignee: TAIWAN SEMICONDUCTOR MANUFACTURING COMPANY, LTD., Hsinchu (TW)

(21) Appl. No.: 18/954,136

(22) Filed: Nov. 20, 2024

(51) Int. Cl. H10B 10/00

(52) U.S. Cl. CPC H10B 10/125

(57) ABSTRACT

A memory device includes multiple memory cells (MCs). For each MC: multiple transistors are located in a transistor layer (TL); three bit line segments are located in a first front metal layer (FML) above the TL, and extend along a first direction; two word line segments are respectively located in a second FML above the first FML and an additional FML above the second FML, and extend along a second direction; and two VSS line segments are located in a back metal layer below the TL, and extend along the first direction. For first and second MCs adjacent in the second direction, a source/drain region of a transistor of the first MC and a source/drain region of a transistor of the second MC are electrically connected through a contact located in an upper portion of the TL and extending from the first MC to the second MC.

### BACKGROUND

The semiconductor integrated circuit (IC) industry has, over the decades, experienced tremendous advancements and is still undergoing vigorous development. With dramatic advances in technology, the industry pays much attention to the development of memory devices with high performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating a memory device in accordance with some embodiments.

FIG. 2 is a circuit diagram illustrating a memory cell in accordance with some embodiments.

FIGS. 3 to 5 are schematic diagrams illustrating relative positions (in an X direction and a Y direction) of various components of a memory cell in accordance with some embodiments.

FIGS. 6 to 12 are schematic sectional views of the memory cell respectively taken along lines C1-C1, C2-C2, C3-C3, C4-C4, C5-C5, C6-C6 and C7-C7 of FIGS. 3 to 5 in accordance with some embodiments.

FIGS. 13 to 15 are schematic diagrams illustrating relative positions (in an X direction and a Y direction) of various components of a memory device in accordance with some embodiments.

FIG. 16 is a schematic diagram illustrating relative positions (in an X direction and a Y direction) of various components of a memory cell in accordance with some embodiments.

FIG. 17 is a schematic diagram illustrating relative positions (in an X direction and a Y direction) of various components of a memory cell in accordance with some embodiments.

FIG. 18 is a schematic diagram illustrating relative positions (in an X direction and a Y direction) of various components of a memory cell in accordance with some embodiments.

FIG. 19 is a schematic sectional view of a memory device in accordance with some embodiments.

FIG. 20 is a top view of a bump pad layer in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

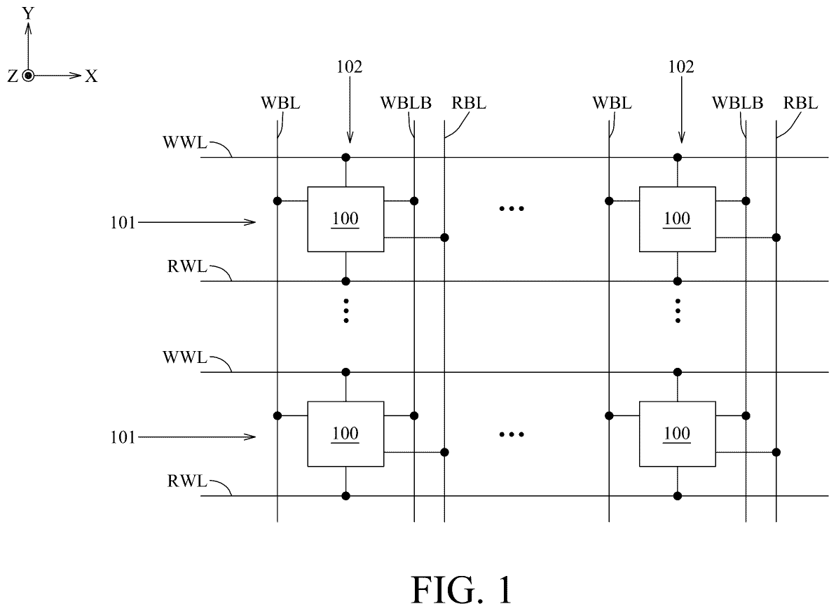

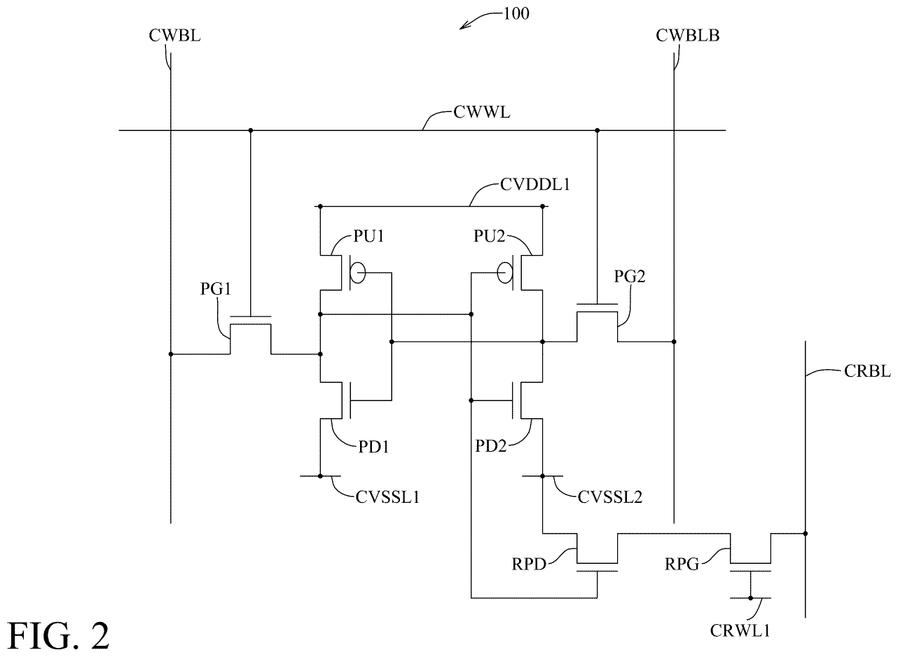

FIG. 1 is a block diagram illustrating a memory device in accordance with some embodiments. FIG. 2 is a circuit diagram illustrating a memory cell in accordance with some embodiments. Referring to FIGS. 1 and 2, the memory device includes a plurality of memory cells 100. The memory cells 100 are arranged in a matrix that has a plurality of rows 101 aligned in a first direction (e.g., a Y direction transverse to a Z direction, where the Z direction points from bottom to top of the memory device) and a plurality of columns 102 aligned in a second direction (e.g., an X direction transverse to the Y direction and the Z direction).

Each of the memory cells 100 is a two-port static random access memory (SRAM) cell, and includes a first pull-up transistor (PU1), a second pull-up transistor (PU2), a first pull-down transistor (PD1), a second pull-down transistor (PD2), a first pass-gate transistor (PG1), a second pass-gate transistor (PG2), a read pull-down transistor (RPD), a read pass-gate transistor (RPG), a non-inverting write bit line segment (CWBL), an inverting write bit line segment (CWBLB), a read bit line segment (CRBL), a write word line segment (CWWL), a read word line segment (CRWL1), a VDD line segment (CVDDL1), a first VSS line segment (CVSSL1), a second VSS line segment (CVSSL2) and a third VSS line segment (not shown). Each of the first pull-up transistor (PU1), the second pull-up transistor (PU2), the first pull-down transistor (PD1), the second pull-down transistor (PD2), the first pass-gate transistor (PG1), the second pass-gate transistor (PG2), the read pull-down transistor (RPD) and the read pass-gate transistor (RPG) includes a gate electrode, a first source/drain region and a second source/drain region. The first source/drain region of the first pull-up transistor (PU1), the first source/drain region of the first pull-down transistor (PD1), the first source/drain region of the first pass-gate transistor (PG1), the gate electrode of the second pull-up transistor (PU2), the gate electrode of the second pull-down transistor (PD2) and the gate electrode of the read pull-down transistor (RPD) are electrically connected to each other. The first source/drain region of the second pull-up transistor (PU2), the first source/drain region of the second pull-down transistor (PD2), the first source/drain region of the second pass-gate transistor (PG2), the gate electrode of the first pull-up transistor (PU1) and the gate electrode of the first pull-down transistor (PD1) are electrically connected to each other. The first source/drain region of the read pull-down transistor (RPD) and the first source/drain region of the read pass-gate transistor (RPG) are electrically connected to each other. The second source/drain region of the first pull-up transistor (PU1) and the second source/drain region of the second pull-up transistor (PU2) are electrically connected to the VDD line segment (CVDDL1). The second source/drain region of the first pull-down transistor (PD1) is electrically connected to the first VSS line segment (CVSSL1). The second source/drain region of the second pull-down transistor (PD2) and the second source/drain region of the read pull-down transistor (RPD) are electrically connected to the second VSS line segment (CVSSL2). The gate electrode of the first pass-gate transistor (PG1) and the gate electrode of the second pass-gate transistor (PG2) are electrically connected to the write word line segment (CWWL). The second source/drain region of the first pass-gate transistor (PG1) is electrically connected to the non-inverting write bit line segment (CWBL). The second source/drain region of the second pass-gate transistor (PG2) is electrically connected to the inverting write bit line segment (CWBLB). The gate electrode of the read pass-gate transistor (RPG) is electrically connected to the read word line segment (CRWL1). The second source/drain region of the read pass-gate transistor (RPG) is electrically connected to the read bit line segment (CRBL). The third VSS line segment is electrically connected to the first VSS line segment (CVSSL1) and the second VSS line segment (CVSSL2). Therefore, the first pull-up transistor (PU1) and the first pull-down transistor (PD1) cooperatively form a first inverter. The second pull-up transistor (PU2) and the second pull-down transistor (PD2) cooperatively form a second inverter. The first inverter and the second inverter are cross-coupled so as to form a data latch for storing data. When the first pass-gate transistor (PG1) and the second pass-gate transistor (PG2) conduct while the read pass-gate transistor (RPG) does not conduct, a write operation is allowed to be performed on the data latch. When the read pass-gate transistor (RPG) conducts while the first pass-gate transistor (PG1) and the second pass-gate transistor (PG2) do not conduct, a read operation is allowed to be performed on the data latch through the read pull-down transistor (RPD). In addition, the first pull-up transistor (PU1), the second pull-up transistor (PU2), the first pull-down transistor (PD1), the second pull-down transistor (PD2), the first pass-gate transistor (PG1) and the second pass-gate transistor (PG2) cooperatively form a write port portion of the memory device, and the read pull-down transistor (RPD) and the read pass-gate transistor (RPG) cooperatively form a read port portion of the memory device.

With respect to each of the rows 101, the write word line segments (CWWL) of the memory cells 100 in the row 101 are connected in series so as to form a write word line (WWL) that corresponds to the row 101 and that extends in the X direction, and the read word line segments (CRWL1) of the memory cells 100 in the row 101 are connected in series so as to form a read word line (RWL) that corresponds to the row 101 and that extends in the X direction. With respect to each of the columns 102, the non-inverting write bit line segments (CWBL) of the memory cells 100 in the column 102 are connected in series so as to form a non-inverting write bit line (WBL) that corresponds to the column 102 and that extends in the Y direction, the inverting write bit line segments (CWBLB) of the memory cells 100 in the column 102 are connected in series so as to form an inverting write bit line (WBLB) that corresponds to the column 102 and that extends in the Y direction, and the read bit line segments (CRBL) of the memory cells 100 in the column 102 are connected in series so as to form a read bit line (RBL) that corresponds to the column 102 and that extends in the Y direction.

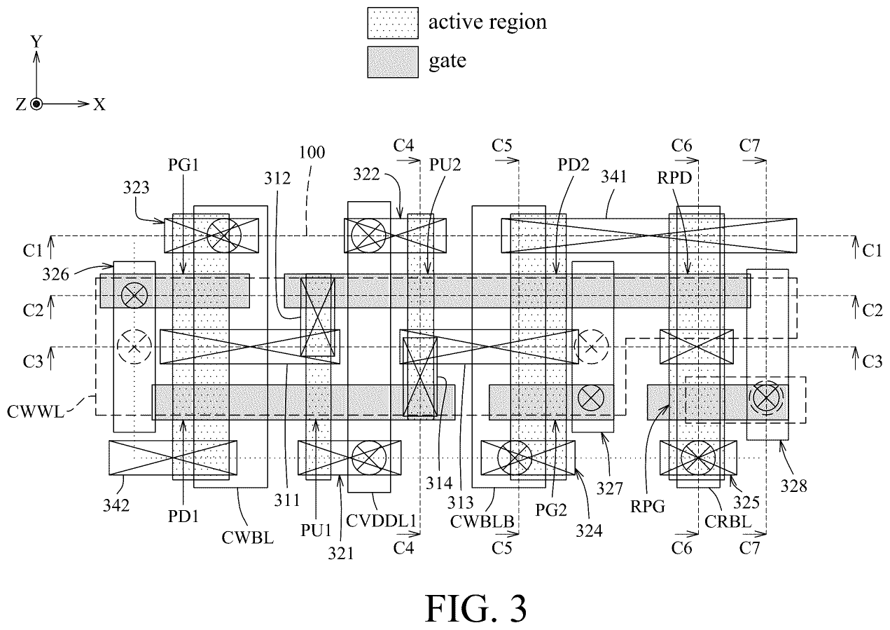

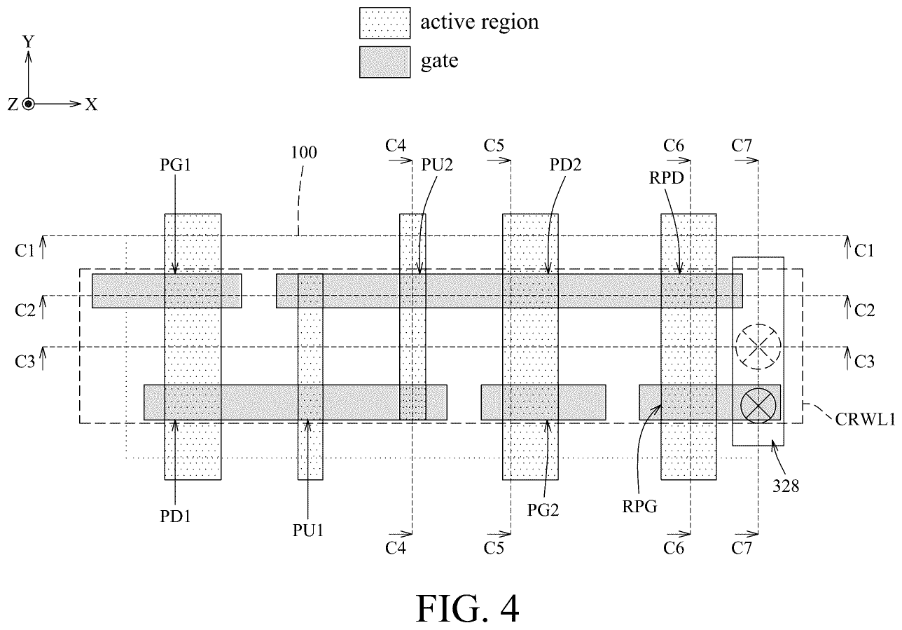

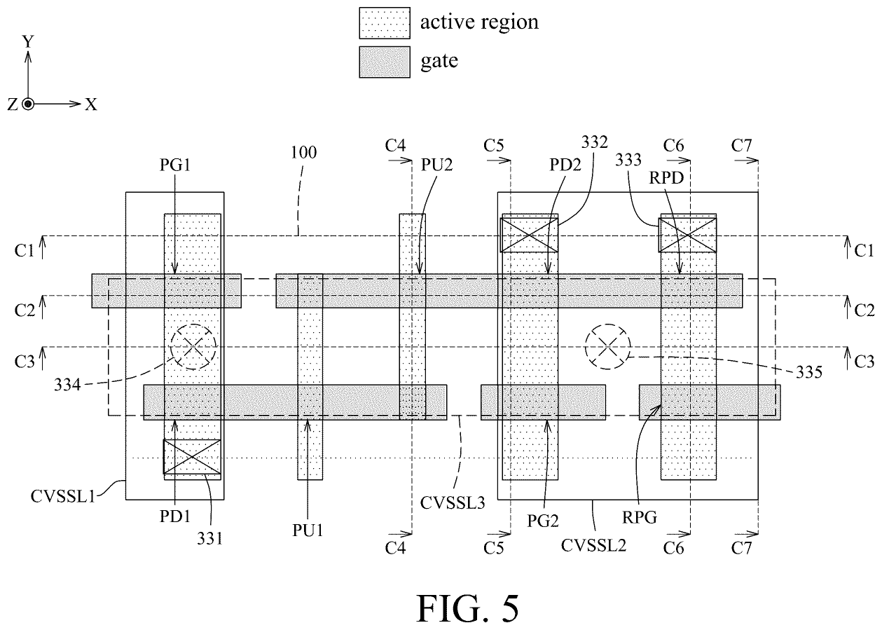

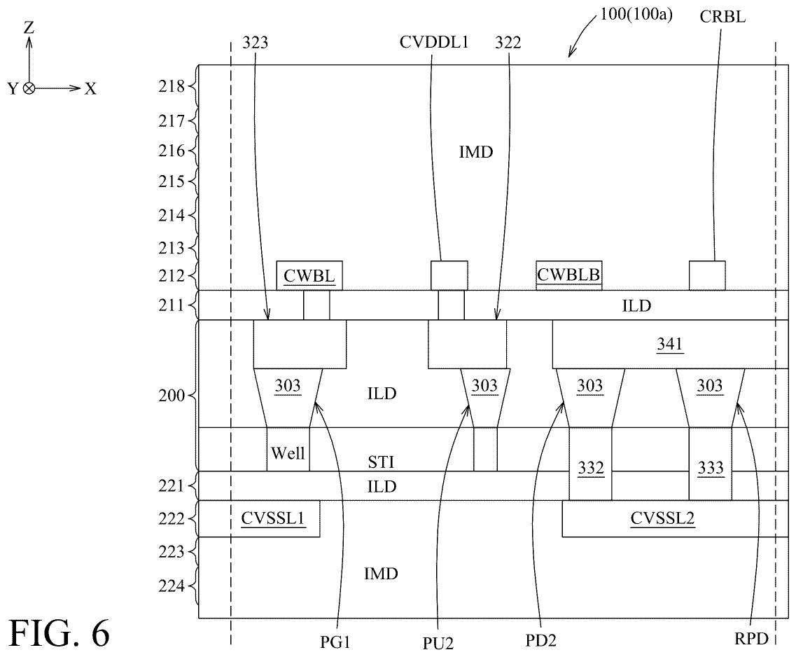

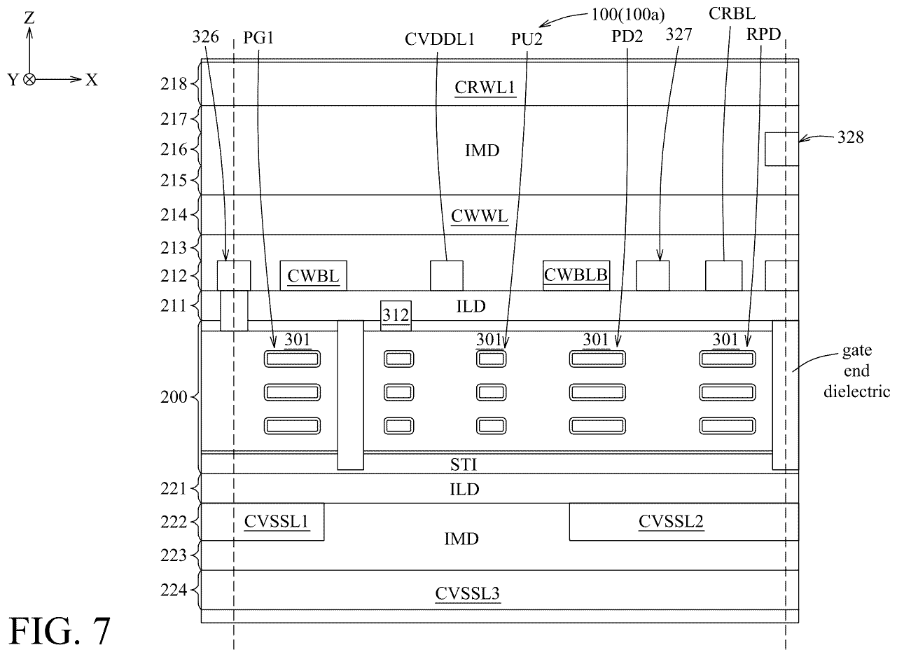

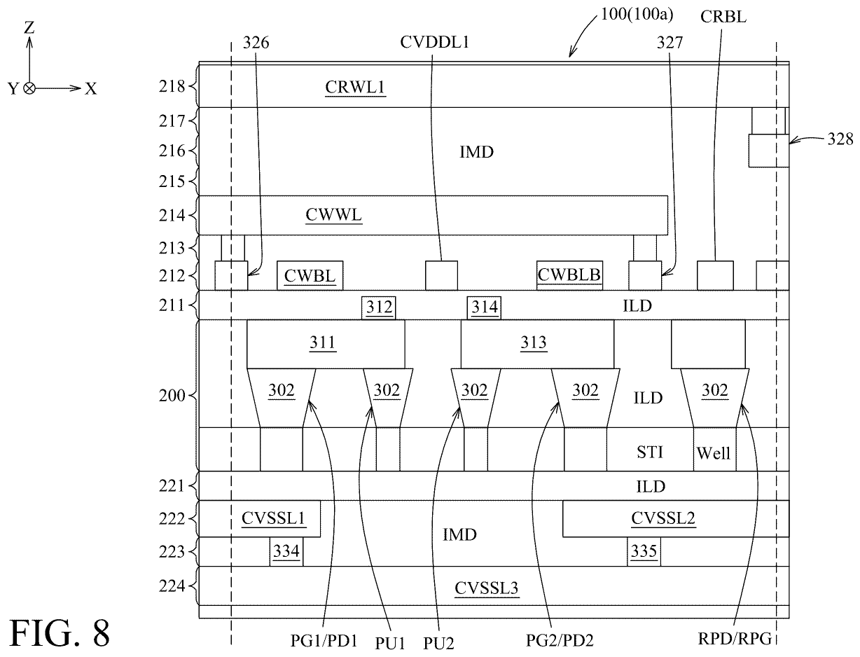

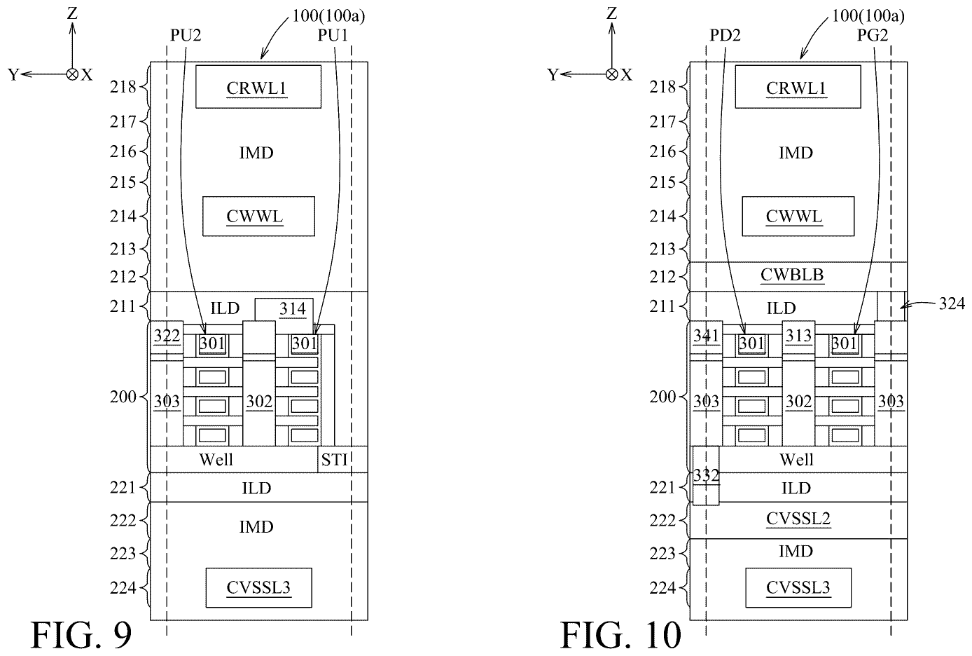

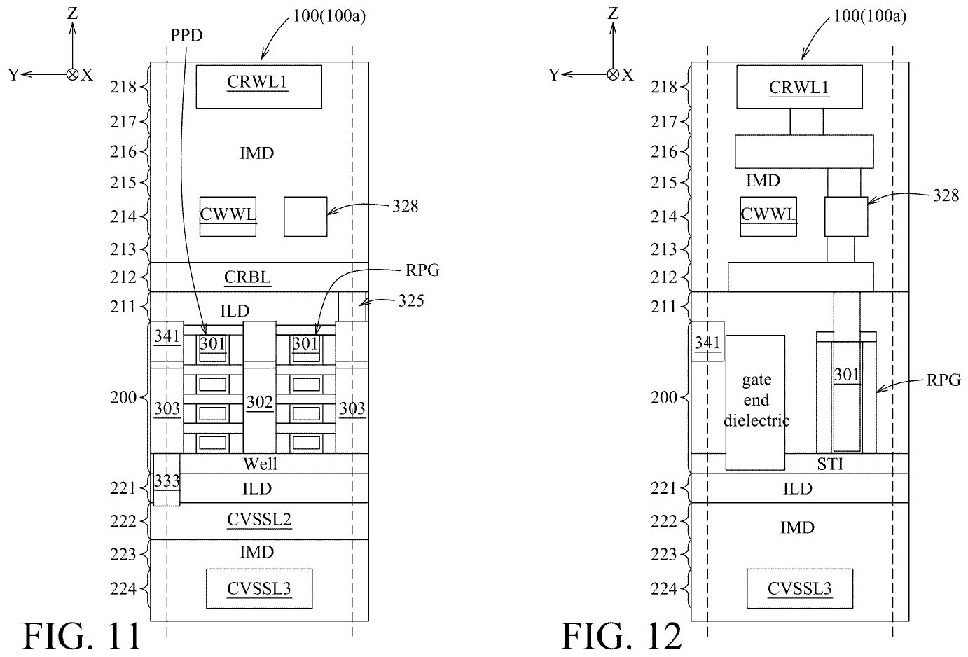

FIGS. 3 to 5 are schematic diagrams illustrating relative positions (in the X direction and the Y direction) of various components of a memory cell in accordance with some embodiments. FIGS. 6 to 12 are schematic sectional views of the memory cell respectively taken along lines C1-C1, C2-C2, C3-C3, C4-C4, C5-C5, C6-C6 and C7-C7 of FIGS. 3 to 5 in accordance with some embodiments. It should be noted that each of FIGS. 3 to 5 omits the depiction of some components of the memory cell for the sake of clarity.

Referring to FIGS. 3 to 12, with respect to each of the memory cells 100, the first pull-up transistor (PU1), the second pull-up transistor (PU2), the first pull-down transistor (PD1), the second pull-down transistor (PD2), the first pass-gate transistor (PG1), the second pass-gate transistor (PG2), the read pull-down transistor (RPD) and the read pass-gate transistor (RPG) are located in a transistor layer 200. The non-inverting write bit line segment (CWBL), the inverting write bit line segment (CWBLB), the read bit line segment (CRBL) and the VDD line segment (CVDDL1) are located in a first front metal layer 212 stacked on the transistor layer 200, and each extend along the Y direction. The inverting write bit line segment (CWBLB) and the VDD line segment (CVDDL1) are disposed between the non-inverting write bit line segment (CWBL) and the read bit line segment (CRBL), with the inverting write bit line segment (CWBLB) adjacent to the read bit line segment (CRBL) and the VDD line segment (CVDDL1) adjacent to the non-inverting write bit line segment (CWBL). The write word line segment (CWWL) is located in a second front metal layer 214 stacked on the first front metal layer 212, and extends along the X direction. The read word line segment (CRWL1) is located in an additional front metal layer stacked on the second front metal layer 214, and extends along the X direction. FIGS. 3 to 12 depict an example where the additional front metal layer is a fourth front metal layer 218. The first VSS line segment (CVSSL1) and the second VSS line segment (CVSSL2) are located in a first back metal layer 222 disposed below the transistor layer 200, and each extend along the Y direction. The third VSS line segment (CVSSL3) is located in a second back metal layer 224 disposed below the first back metal layer 222, and extends along the X direction. The gate electrode of each of the first pull-up transistor (PU1), the second pull-up transistor (PU2), the first pull-down transistor (PD1), the second pull-down transistor (PD2), the first pass-gate transistor (PG1), the second pass-gate transistor (PG2), the read pull-down transistor (RPD) and the read pass-gate transistor (RPG) extends in the X direction. The first source/drain region 302 of the first pass-gate transistor (PG1) and the first source/drain region 302 of the first pull-down transistor (PD1) share the same region (i.e., the first pass-gate transistor (PG1) and the first pull-down transistor (PD1) have a common first source/drain region 302). The common first source/drain region 302 of the first pass-gate transistor (PG1) and the first pull-down transistor (PD1) is connected to the first source/drain region 302 of the first pull-up transistor (PU1) through a front contact 311 that is located in an upper portion of the transistor layer 200. The front contact 311 is connected to the gate electrode 301 of the second pull-up transistor (PU2) through a front contact 312 that is located in a bottom front via layer 211 disposed between the first front metal 212 and the transistor layer 200. The gate electrode 301 of the second pull-up transistor (PU2), the gate electrode 301 of the second pull-down transistor (PD2) and the gate electrode of the read pull-down transistor (RPD) are connected in series. Accordingly, the electrical connection among the first source/drain region 302 of the first pass-gate transistor (PG1), the first source/drain region 302 of the first pull-down transistor (PD1), the first source/drain region 302 of the first pull-up transistor (PU1), the gate electrode 301 of the second pull-up transistor (PU2), the gate electrode 301 of the second pull-down transistor (PD2) and the gate electrode of the read pull-down transistor (RPD) is established. The first source/drain region 302 of the second pass-gate transistor (PG2) and the first source/drain region 302 of the second pull-down transistor (PD2) share the same region (i.e., the second pass-gate transistor (PG2) and the second pull-down transistor (PD2) have a common first source/drain region 302). The common first source/drain region 302 of the second pass-gate transistor (PG2) and the second pull-down transistor (PD2) is connected to the first source/drain region 302 of the second pull-up transistor (PU2) through a front contact 313 that is located in the upper portion of the transistor layer 200. The front contact 313 is connected to the gate electrode of the first pull-up transistor (PU1) through a front contact 314 that is located in the bottom front via layer 211. The gate electrode of the first pull-up transistor (PU1) and the gate electrode of the first pull-down transistor (PD1) are connected in series. Accordingly, the electrical connection among the first source/drain region 302 of the second pass-gate transistor (PG2), the first source/drain region 302 of the second pull-down transistor (PD2), the first source/drain region 302 of the second pull-up transistor (PU2), the gate electrode of the first pull-up transistor (PU1) and the gate electrode of the first pull-down transistor (PD1) is established. The first source/drain region 302 of the read pull-down transistor (RPD) and the first source/drain region 302 of the read pass-gate transistor (RPD) share the same region (i.e., the read pull-down transistor (RPD) and the read pass-gate transistor (RPD) have a common first source/drain region 302), so as to establish the electrical connection between the first source/drain region 302 of the read pull-down transistor (RPD) and the first source/drain region 302 of the read pass-gate transistor (RPD). The second source/drain region of the first pull-up transistor (PU1) is electrically connected to the VDD line segment (CVDDL1) through an interconnect element 321 that includes a front contact located in the upper portion of the transistor layer 200 and a front via located in the bottom front via layer 211. The second source/drain region 303 of the second pull-up transistor (PU2) is electrically connected to the VDD line segment (CVDDL1) through an interconnect element 322 that includes a front contact located in the upper portion of the transistor layer 200 and a front via located in the bottom front via layer 211. The second source/drain region 303 of the first pass-gate transistor (PG1) is electrically connected to the non-inverting write bit line segment (CWBL) through an interconnect element 323 that includes a front contact located in the upper portion of the transistor layer 200 and a front via located in the bottom front via layer 211. The second source/drain region of the second pass-gate transistor (PG2) is electrically connected to the inverting write bit line segment (CWBLB) through an interconnect element 324 that includes a front contact located in the upper portion of the transistor layer 200 and a front via located in the bottom front via layer 211. The second source/drain region of the read pass-gate transistor (RPG) is electrically connected to the read bit line segment (CRBL) through an interconnect element 325 that includes a front contact located in the upper portion of the transistor layer 200 and a front via located in the bottom front via layer 211. The gate electrode 301 of the first pass-gate transistor (PG1) is electrically connected to the write word line segment (CWWL) through an interconnect element 326 that includes a front via located in the bottom front via layer 211, a front landing pad located in the first front metal layer 212, and another front via located in a first front via layer 213 disposed between the second front metal layer 214 and the first front metal layer 212. The gate electrode of the second pass-gate transistor (PG2) is electrically connected to the write word line segment (CWWL) through an interconnect element 327 that includes a front via located in the bottom front via layer 211, a front landing pad located in the first front metal layer 212, and another front via located in the first front via layer 213. The gate electrode of the read pass-gate transistor (RPG) is electrically connected to the read word line segment (CRWL1) through an interconnect element 328 that includes a first front via located in the bottom front via layer 211, a first front landing pad located in the first front metal layer 212, a second front via located in the first front via layer 213, a second front landing pad located in the second front metal layer 214, a third front via located in a second front via layer 215 disposed between the fourth front metal layer 218 and the second front metal layer 214, a third front landing pad located in a third front metal layer 216 disposed between the fourth front metal layer 218 and the second front via layer 215, and a fourth front via located in a third front via layer 217 disposed between the fourth front metal layer 218 and the third front metal layer 216. The second source/drain region of the first pull-down transistor (PD1) is electrically connected to the first VSS line segment (CVSSL1) through a back contact 331 that is located in a lower portion of the transistor layer 200 and in a top back via layer 221 disposed between the transistor layer 200 and the first back metal layer 222. The second source/drain region 303 of the second pull-down transistor (PD2) is electrically connected to the second VSS line segment (CVSSL2) through a back contact 332 that is located in the lower portion of the transistor layer 200 and the top back via layer 221. The second source/drain region 303 of the read pull-down transistor (RPD) is electrically connected to the second VSS line segment (CVSSL2) through a back contact 333 that is located in the lower portion of the transistor layer 200 and the top back via layer 221. The third VSS line segment (CVSSL3) is electrically connected to the first VSS line segment (CVSSL1) through a back via 334 that is located in a first back via layer 223 disposed between the first back metal layer 222 and the second back metal layer 224, and is electrically connected to the second VSS line segment (CVSSL2) through a back via 335 that is located in the first back via layer 223.

In some embodiments, each of the transistors (PU1, PU2, PD1, PD2, PG1, PG2, RPD, RPG) of each of the memory cells 100 may be a planar field effect transistor (planar FET), a three-dimensional field effect transistor (3D FET) such as a fin field effect transistor (FinFET), a nanosheet gate-all-around field effect transistor (GAAFET), a nanowire GAAFET, a forksheet field effect transistor, a complementary field effect transistor (CFET), or other suitable FETs. FIGS. 6 to 12 depict an example where each of the transistors (PU1, PU2, PD1, PD2, PG1, PG2, RPD, RPG) of each of the memory cells 100 is a nanosheet GAAFET.

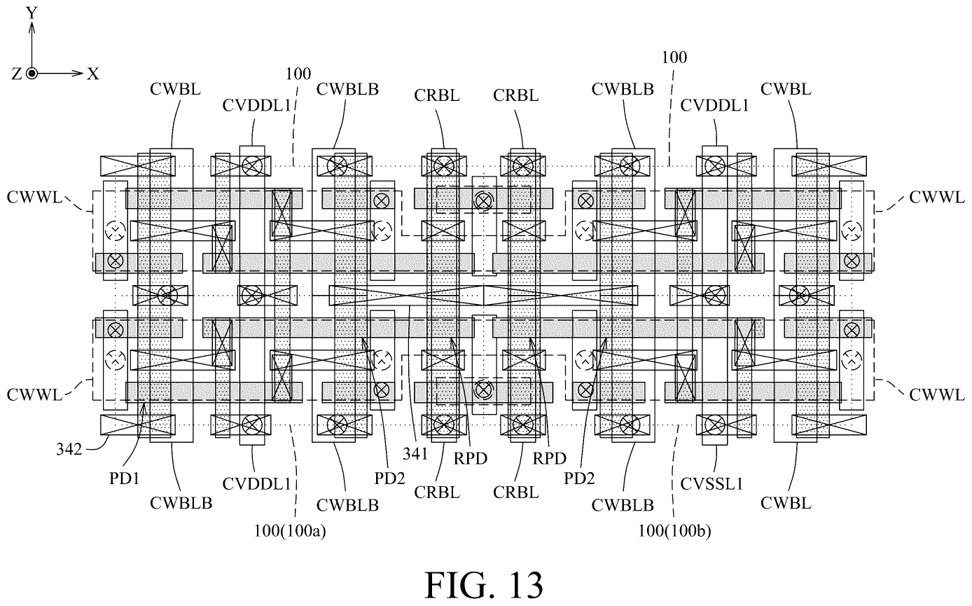

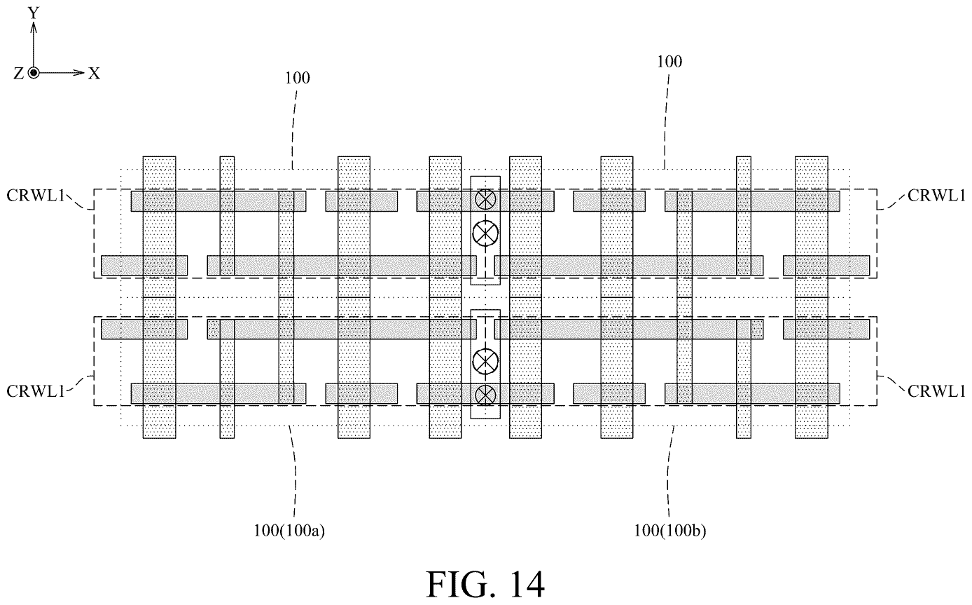

FIGS. 13 to 15 are schematic diagrams illustrating relative positions (in an X direction and a Y direction) of various components of a memory device in accordance with some embodiments. It should be noted that: only four of memory cells 100 of the memory device are depicted in FIGS. 13 to 15; and each of FIGS. 13 to 15 omits the depiction of some components of the four memory cells 100 for the sake of clarity.

Referring to FIGS. 1 and 13 to 15, with respect to each of the rows 101: any two adjacent ones of the memory cells 100 in the row 101 are mirror symmetric with each other about a plane transverse to the X direction; the write word line segments (CWWL) of any two adjacent ones of the memory cells 100 in the row 101 are in contact with each other, so the write word line segments (CWWL) of the memory cells 100 in the row 101 cooperatively form the write word line (WWL) that corresponds to the row 101; the read word line segments (CRWL1) of any two adjacent ones of the memory cells 100 in the row 101 are in contact with each other, so the read word line segments (CRWL1) of the memory cells 100 in the row 101 cooperatively form the read word line (RWL) that corresponds to the row 101; and the third VSS line segments (CVSSL3) of any two adjacent ones of the memory cells 100 in the row 101 are in contact with each other, so the third VSS line segments (CVSSL3) of the memory cells 100 in the row 101 cooperatively form a third VSS line that corresponds to the row 101.

With respect to each of the columns 102: any two adjacent ones of the memory cells 100 in the column 102 have mirror symmetry with each other about a plane transverse to the Y direction; the non-inverting write bit line segments (CWBL) of any two adjacent ones of the memory cells 100 in the column 102 are in contact with each other, so the non-inverting write bit line segments (CWBL) of the memory cells 100 in the column 102 cooperatively form the non-inverting write bit line (WBL) that corresponds to the column 102; the inverting write bit line segments (CWBLB) of any two adjacent ones of the memory cells 100 in the column 102 are in contact with each other, so the inverting write bit line segments (CWBLB) of the memory cells 100 in the column 102 cooperatively form the inverting write bit line (WBLB) that corresponds to the column 102; the read bit line segments (CRBL) of any two adjacent ones of the memory cells 100 in the column 102 are in contact with each other, so the read bit line segments (CRBL) of the memory cells 100 in the column 102 cooperatively form the read bit line (RBL) that corresponds to the column 102; the VDD line segments (CVDDL1) of any two adjacent ones of the memory cells 100 in the column 102 are in contact with each other, so the VDD line segments (CVDDL1) of the memory cells 100 in the column 102 cooperatively form a VDD line that corresponds to the column 102 and that is for transmitting a first supply voltage; the first VSS line segments (CVSSL1) of any two adjacent ones of the memory cells 100 in the column 102 are in contact with each other, so the first VSS line segments (CVSSL1) of the memory cells 100 in the column 102 cooperatively form a first VSS line that corresponds to the column 102 and that is for transmitting a second supply voltage lower than the first supply voltage in magnitude; and the second VSS line segments (CVSSL2) of any two adjacent ones of the memory cells 100 in the column 102 are in contact with each other, so the second VSS line segments (CVSSL2) of the memory cells 100 in the column 102 cooperatively form a second VSS line that corresponds to the column 102 and that is for transmitting the second supply voltage.

By virtue of the third VSS lines electrically connecting the first VSS lines and the second VSS lines in parallel, a line resistance (in the Y direction) from a combination of the first VSS lines and the second VSS lines can be reduced, thereby reducing a voltage drop caused by the combination of the first VSS lines and the second VSS lines, reducing power consumption of the memory device, and increasing a maximum operating speed of the memory device.

Referring to FIGS. 1, 6 and 13 to 15, with respect to any two of the memory cells 100 that are adjacent to each other in the X direction (one of which is also referred to as a first memory cell (100a) hereinafter, and the other one of which is also referred to as a second memory cell (100b) hereinafter), the second source/drain region of the second pull-down transistor (PD2) of the first memory cell (100a), the second source/drain region of the read pull-down transistor (RPD) of the first memory cell (100a), the second source/drain region of the read pull-down transistor (RPD) of the second memory cell (100b) and the second source/drain region of the second pull-down transistor (PD2) of the second memory cell (100b) are electrically connected to each other through a front contact 341 that is located in the upper portion of the transistor layer 200 and that extends from a cell region of the first memory cell (100a) to a cell region of the second memory cell (100b) along the X direction, so as to reduce a line resistance (in the Y direction) from a combination of the second VSS line segment (CVSSL2) of the first memory cell (100a) and the second VSS line segment (CVSSL2) of the second memory cell (100b). Therefore, the line resistance (in the Y direction) from the combination of the first VSS lines and the second VSS lines can be reduced, thereby reducing the voltage drop caused by the combination of the first VSS lines and the second VSS lines, reducing the power consumption of the memory device, and increasing the maximum operating speed of the memory device. In addition, the memory device can still work even if at most three of the back contacts 332, 333 of the first memory cell (100a) and the second memory cell (100b) have failed, so yield of the memory device can be enhanced. Similarly, with respect to the first memory cell (100a) and a third memory cell 100 that is adjacent to the first memory cell (100a) and opposite to the second memory cell (100b) in the X direction, the second source/drain region of the first pull-down transistor (PD1) of the first memory cell (100a) and the second source/drain region of the first pull-down transistor (PD1) of the third memory cell 100 may be electrically connected to each other through a front contact 342 that is located in the upper portion of the transistor layer 200 and that extends from a cell region of the third memory cell 100 to the cell region of the first memory cell (100a) along the X direction, so as to reduce a line resistance (in the Y direction) from a combination of the first VSS line segment (CVSSL1) of the first memory cell (100a) and the first VSS line segment (CVSSL1) of the third memory cell 100. Therefore, the line resistance (in the Y direction) from the combination of the first VSS lines and the second VSS lines can be reduced, thereby reducing the voltage drop caused by the combination of the first VSS lines and the second VSS lines, reducing the power consumption of the memory device, and increasing the maximum operating speed of the memory device. In addition, the memory device can still work even if one of the back contacts 331 of the first memory cell (100a) and the third memory cell 100 has failed, so the yield of the memory device can be enhanced.

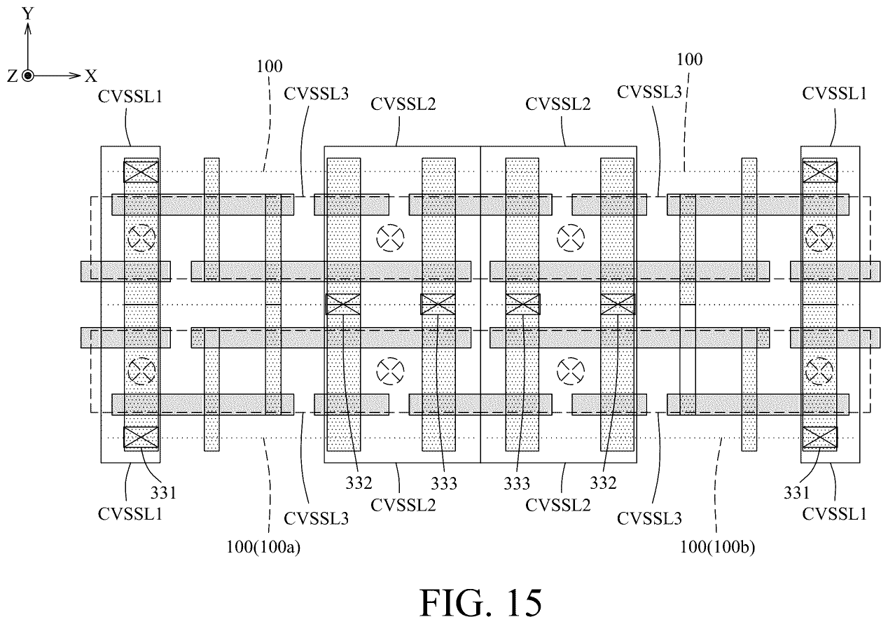

In some embodiments, the first or second VSS line segment (CVSSL1/CVSSL2) of the first memory cell (100a) and the first or second VSS line segment (CVSSL1/CVSSL2) of the second memory cell (100b) that are adjacent to each other (e.g., the second VSS line segment (CVSSL2) of the first memory cell (100a) and the second VSS line segment (CVSSL2) of the second memory cell (100b) as depicted in FIG. 15) may be in contact with each other, so as to further reduce the line resistance (in the Y direction) from the combination of the first or second VSS line segment (CVSSL1/CVSSL2) of the first memory cell (100a) and the first or second VSS line segment (CVSSL1/CVSSL2) of the second memory cell (100b) that are adjacent to each other.

In the cell region of each of the memory cells 100, the first front metal layer 212 is free of the first VSS line segment (CVSSL1) and the second VSS line segment (CVSSL2). This can facilitate shrinking of the memory device. In addition, the first front metal layer 212 can have more space for the non-inverting write bit line segment (CWBL), the inverting write bit line segment (CWBLB) and the read bit line segment (CRBL), and each of the non-inverting write bit line segment (CWBL), the inverting write bit line segment (CWBLB) and the read bit line segment (CRBL) can be wide so as to have a low line resistance (in the Y direction). Therefore, the non-inverting write bit lines (WBL) that respectively correspond to the columns 102, the inverting write bit lines (WBLB) that respectively correspond to the columns 102, and the read bit lines (RBL) that respectively correspond to the columns 102 can each have a low line resistance (in the Y direction), and can thus cause a low resistance-capacitance (RC) time delay. This is beneficial to increasing the maximum operating speed of the memory device and reducing a minimum write voltage of the memory device.

In the cell region of each of the memory cells 100, since the first back metal layer 222 only includes the first VSS line segment (CVSSL1) and the second VSS line segment (CVSSL2), each of first VSS line segment (CVSSL1) and the second VSS line segment (CVSSL2) can be wide so as to have a low line resistance (in the Y direction). Therefore, the first VSS lines that respectively correspond to the columns 102 and the second VSS lines that respectively correspond to the columns 102 can each have a low line resistance (in the Y direction), and can thus cause a low voltage drop. This is beneficial to reducing the power consumption of the memory device and increasing the maximum operating speed of the memory device.

In the cell region of each of the memory cells 100, since the second front metal layer 214 mainly includes the write word line segment (CWWL), the write word line segment (CWWL) can be made wider to occupy most of the second front metal layer 214 so as to have a low line resistance (in the X direction). Therefore, the write word lines (WWL) that respectively correspond to the rows 101 can each have a low line resistance (in the X direction), and can thus cause a low RC time delay. This is beneficial to increasing the maximum operating speed of the memory device.

In the cell region of each of the memory cells 100, since the additional front metal layer (i.e., the fourth front metal layer 218) only includes the read word line segment (CRWL1), the read word line segment (CRWL1) can be made wider so as to have a low line resistance (in the X direction). Therefore, the read word lines (RWL) that respectively correspond to the rows 101 can each have a low line resistance (in the X direction), and can thus cause a low RC time delay. This is beneficial to increasing the maximum operating speed of the memory device.

In some embodiments, with respect to each of the memory cells 100, the second source/drain region of the first pull-down transistor (PD1) may be electrically connected to the first VSS line segment (CVSSL1) through not only the back contact 331 but also a back via (not shown) that is located in a top back via layer (not shown) disposed between the back contact layer 221 and the first back metal layer 222. The second source/drain region 303 of the second pull-down transistor (PD2) may be electrically connected to the second VSS line segment (CVSSL2) through not only the back contact 332 but also a back via (not shown) that is located in the top back via layer.

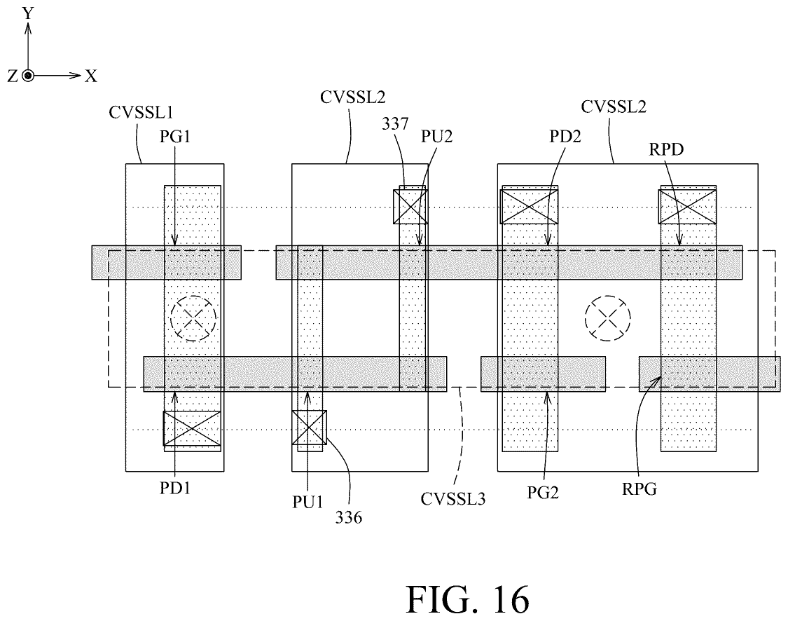

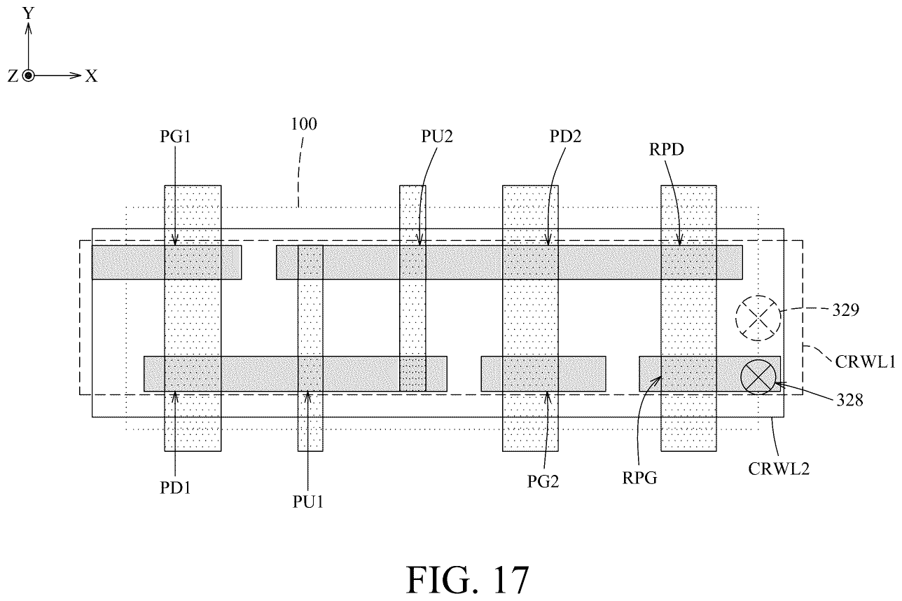

FIG. 16 is a schematic diagram illustrating relative positions (in the X direction and the Y direction) of various components of a memory cell in accordance with some embodiments. It should be noted that FIG. 16 omits the depiction of some components of the memory cell for the sake of clarity. Referring to FIGS. 1, 3, 4 and 16, the memory device depicted in FIGS. 1, 3, 4 and 16 is similar to the memory device described with reference to FIGS. 1 to 12, but differs therefrom in that each of the memory cells 100 of the memory device depicted in FIGS. 1, 3, 4 and 16 further includes another VDD line segment (CVDDL2). The VDD line segment (CVDDL2) is located in the first back metal layer 222 (see FIG. 6), extends along the Y direction, and is disposed between the first VSS line segment (CVSSL1) and the second VSS line segment (CVSSL2). The VDD line segment (CVDDL2) is electrically connected to the second source/drain region of the first pull-up transistor (PU1) through a back contact 336 located in the lower portion of the transistor layer 200 (see FIG. 6) and the back contact layer 221 (see FIG. 6), and is electrically connected to the second source/drain region of the second pull-up transistor (PU2) through a back contact 337 located in the lower portion of the transistor layer 200 (see FIG. 6) and the back contact layer 221 (see FIG. 6), so the VDD line segment (CVDDL1) and the VDD line segment (CVDDL2) are electrically connected to each other. With respect to each of the columns 102, the VDD line segments (CVDDL2) of any two adjacent ones of the memory cells 100 in the column 102 are in contact with each other, and the VDD line segments (CVDDL2) of the memory cells 100 in the column 102 cooperate with the VDD line segments (CVDDL1) of the memory cells 100 in the column 102 to form the VDD line that corresponds to the column 102. Therefore, the VDD lines that respectively correspond to the columns 102 can each have a low line resistance (in the Y direction), and can thus cause a low voltage drop. This is beneficial to reducing the power consumption of the memory device and increasing the maximum operating speed of the memory device.

FIG. 17 is a schematic diagram illustrating relative positions (in the X direction and the Y direction) of various components of a memory cell in accordance with some embodiments. It should be noted that FIG. 17 omits the depiction of some components of the memory cell for the sake of clarity. Referring to FIGS. 1, 3, 5 and 17, the memory device depicted in FIGS. 1, 3, 5 and 17 is similar to the memory device described with reference to FIGS. 1 to 12, but differs therefrom in that each of the memory cells 100 further includes another read word line segment (CRWL2). The read word line segment (CRWL2) is located in the third front metal layer 216 (see FIG. 6), extends along the X direction, is electrically connected to the gate electrode of the read pass-gate transistor (RPG) through the interconnect element 328 where the third front landing pad located in the third front metal layer 216 (see FIG. 6) and the fourth front via located in the third front via layer 217 (see FIG. 6) are omitted, and is electrically connected to the read word line segment (CRWL1) through a front via 329 located in the third front via layer 217 (see FIG. 6). With respect to each of the rows 101, the read word line segment (CRWL2) of any two adjacent ones of the memory cells 100 in the row 101 are in contact with each other, and the read word line segment (CRWL2) of the memory cells 100 in the row 101 cooperate with the read word line segment (CRWL1) of the memory cells 100 in the row 101 to form the read word line (RWL) that corresponds to the row 101. Therefore, the read word lines (RWL) that respectively correspond to the rows 101 can each have a low line resistance (in the X direction), and can thus provide a low RC time delay. This is beneficial to increasing the maximum operating speed of the memory device.

In the cell region of each of the memory cells 100, since the third front metal layer 216 (see FIG. 6) only includes the read word line segment (CRWL2), the read word line segment (CRWL2) can be made wider so as to have a low line resistance (in the X direction). Therefore, the read word lines (RWL) that respectively correspond to the rows 101 can each have a low line resistance (in the X direction), and can thus provide a low RC time delay. This is beneficial to increasing the maximum operating speed of the memory device.

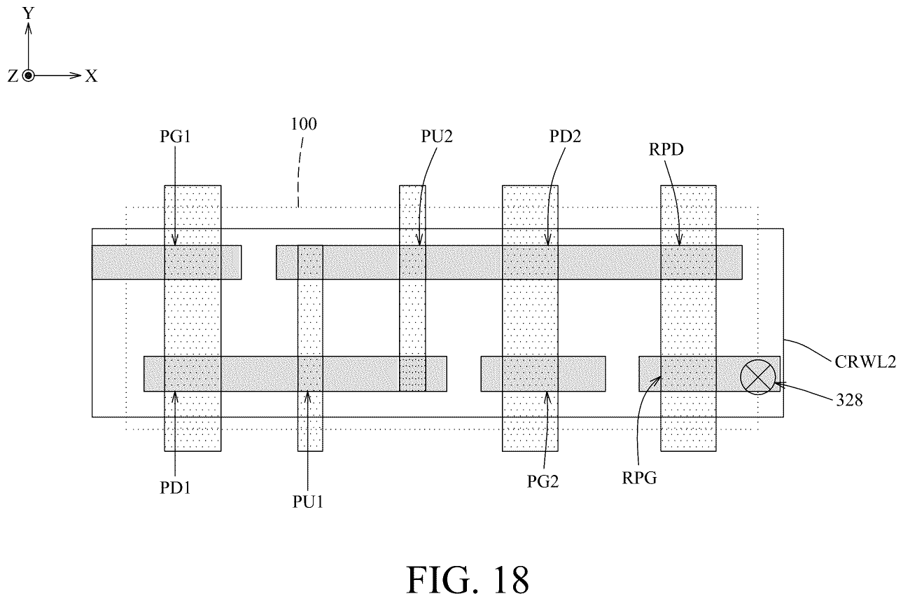

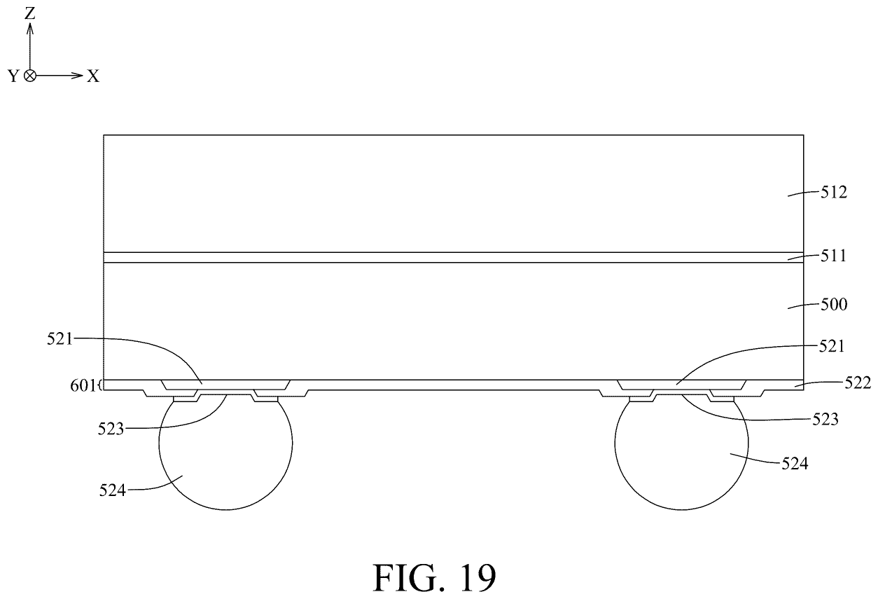

FIG. 18 is a schematic diagram illustrating relative positions (in the X direction and the Y direction) of various components of a memory cell in accordance with some embodiments. It should be noted that FIG. 18 omits the depiction of some components of the memory cell for the sake of clarity. Referring to FIGS. 1, 3, 5 and 18, the memory device depicted in FIGS. 1, 3, 5 and 18 is similar to the memory device depicted in FIGS. 1, 3, 5 and 17, but differs therefrom in that the read word line segment (CRWL1) (see FIG. 17) and the front via 329 (see FIG. 17) of each of the memory cells 100 are omitted.

In the cell region of each of the memory cells 100, since the third front metal layer 216 (see FIG. 6) only includes the read word line segment (CRWL2), the read word line segment (CRWL2) can be made wider so as to have a low line resistance (in the X direction). Therefore, the read word lines (RWL) that respectively correspond to the rows 101 can each have a low line resistance (in the X direction), and can thus provide a low RC time delay. This is beneficial to increasing the maximum operating speed of the memory device.

FIG. 19 is a schematic sectional view of a memory device in accordance with some embodiments. Referring to FIG. 19, the memory device includes a memory feature 500, a dielectric layer 511, a blank substrate 512, a plurality of bump pads 521, a passivation layer 522, a plurality of under bump metallurgy (UBM) films 523 and a plurality of bump balls 524. The memory feature 500 has a structure as depicted in FIG. 1, and 3 to 5. The dielectric layer 511 is disposed on an upper surface of the memory feature 500. The blank substrate 512 (e.g., a silicon substrate) is disposed on an upper surface of the dielectric layer 511. The bump pads 521 are disposed on a lower surface of the memory feature 500. The passivation layer 522 covers a portion of the lower surface of the memory feature 500 that is not covered by the bump pads 521 and also covers an outer portion of a lower surface of each of the bump pads 521, and exposes an inner portion of the lower surface of each of the bump pads 521. Each of the UBM films 523 covers at least the inner portion of the lower surface of a respective one of the bump pads 521. Each of the bump balls 524 is disposed on a lower surface of a respective one of the UBM films 523.

In some embodiments, the bump pads 521 may be made from, for example, Cu, Al, Au, Ag, Pt, Ni, Mo, other suitable materials, or combinations thereof.

Since the bump pads 521 are disposed below the memory feature 500, the third VSS lines of the memory feature 500 can be electrically connected to one of the bump pads 521 through an interconnect element alone, in which the interconnect element has a low resistance and causes a low voltage drop. This is beneficial to reducing the power consumption of the memory device and increasing the maximum operating speed of the memory device.

In some embodiments where the memory feature 500 has a structure as depicted in FIGS. 1, 3, 4 and 16, since the bump pads 521 are disposed below the memory feature 500, the VDD lines of the memory feature 500 can be electrically connected to one of the bump pads 521 through an interconnect element alone, in which the interconnect element has a low resistance and causes a low voltage drop. This is beneficial to reducing the power consumption of the memory device and increasing the maximum operating speed of the memory device.

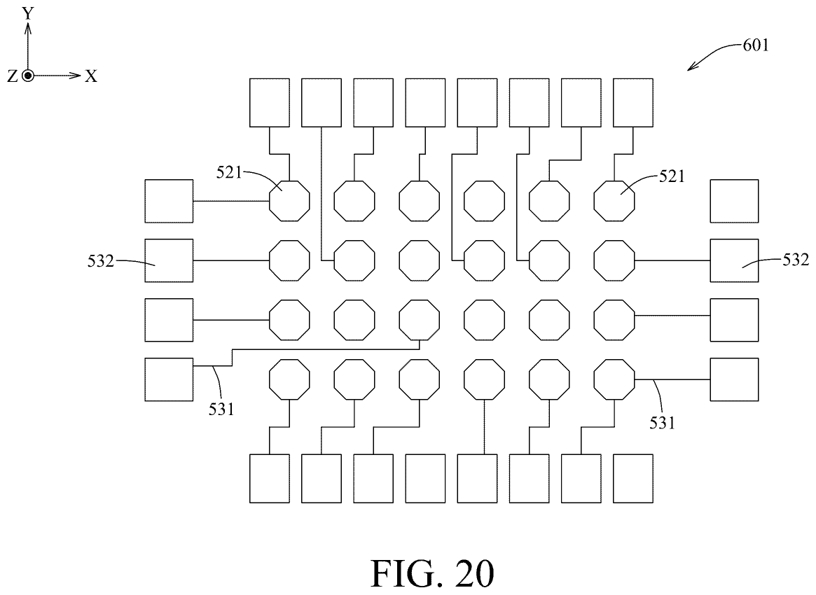

FIG. 20 is a top view of a bump pad layer in accordance with some embodiments. Referring to FIGS. 19 and 20, the bump pad layer 601 is disposed on and located below the memory feature 500, and the bump pads 521 are located in the bump pad layer 601. In addition to the bump pads 521, the bump pad layer 601 may further include a plurality of metal lines 531 and a plurality of test pads 532. Each of the bump pads 521 may be electrically connected to a power line (e.g., a VDD line or a VSS line) or a signal line of the memory feature 500 through an interconnect element that is disposed right above the bump pad 521, or through one of the metal lines 531 and an interconnect element that is disposed above and offset from the bump pad 521. Each of the bump pads 521 may be further electrically connected to one of the test pads 532 through one of the metal lines 531.

In accordance with some embodiments of the present disclosure, a memory device includes a plurality of memory cells which are arranged in a matrix that has a plurality of rows aligned in a first direction and a plurality of columns aligned in a second direction. Each of the plurality of memory cells includes a first pull-up transistor, a second pull-up transistor, a first pull-down transistor, a second pull-down transistor, a first pass-gate transistor, a second pass-gate transistor, a read pull-down transistor, a read pass-gate transistor, a non-inverting write bit line segment, an inverting write bit line segment, a read bit line segment, a write word line segment, a first read word line segment, a first VSS line segment and a second VSS line segment. The first pull-up transistor, the second pull-up transistor, the first pull-down transistor, the second pull-down transistor, the first pass-gate transistor, the second pass-gate transistor, the read pull-down transistor and the read pass-gate transistor are located in a transistor layer, and each include a gate electrode and two source/drain regions, where the first pull-up transistor, the second pull-up transistor, the first pull-down transistor and the second pull-down transistor cooperatively form a data latch for storing data, where when the first pass-gate transistor and the second pass-gate transistor conduct while the read pass-gate transistor does not conduct, a write operation is allowed to be performed on the data latch, and where when the read pass-gate transistor conducts while the first pass-gate transistor and the second pass-gate transistor do not conduct, a read operation is allowed to be performed on the data latch through the read pull-down transistor. The non-inverting write bit line segment, the inverting write bit line segment and the read bit line segment are located in a first front metal layer stacked on the transistor layer, and each extend along the first direction, where the non-inverting write bit line segment is electrically connected to one of the source/drain regions of the first pass-gate transistor, the inverting write bit line segment is electrically connected to one of the source/drain regions of the second pass-gate transistor, and the read bit line segment is electrically connected to one of the source/drain regions of the read pass-gate transistor. The write word line segment is located in a second front metal layer stacked on the first front metal layer, extends along the second direction, and is electrically connected to the gate electrode of the first pass-gate transistor and the gate electrode of the second pass-gate transistor. The first read word line segment is located in an additional front metal layer stacked on the second front metal layer, extends along the second direction, and is electrically connected to the gate electrode of the read pass-gate transistor. The first VSS line segment and the second VSS line segment are located in a first back metal layer disposed below the transistor layer, and each extend along the first direction, where the first VSS line segment is electrically connected to one of the source/drain regions of the first pull-down transistor, and the second VSS line segment is electrically connected to one of the source/drain regions of the second pull-down transistor. With respect to a first memory cell and a second memory cell of the plurality of memory cells that are adjacent to each other in the second direction, the one of the source/drain regions of the second pull-down transistor of the first memory cell and the one of the source/drain regions of the second pull-down transistor of the second memory cell are electrically connected to each other through a front contact that is located in an upper portion of the transistor layer, and that extends from a cell region of the first memory cell to a cell region of the second memory cell along the second direction.

In accordance with some embodiments of the present disclosure, one of the source/drain regions of the read pull-down transistor of the first memory cell and one of the source/drain regions of the read pull-down transistor of the second memory cell are electrically connected to the one of the source/drain regions of the second pull-down transistor of the first memory cell and the one of the source/drain regions of the second pull-down transistor of the second memory cell through the front contact.

In accordance with some embodiments of the present disclosure, with respect to each of the plurality of memory cells, each of the first VSS line segment and the second VSS line segment is electrically connected to the one of the source/drain regions of a corresponding one of the first pull-down transistor and the second pull-down transistor through a back contact that is located in a back contact layer disposed between the transistor layer and the first back metal layer.

In accordance with some embodiments of the present disclosure, the second VSS line segment of the first memory cell is in contact with the second VSS line segment of the second memory cell.

In accordance with some embodiments of the present disclosure, each of the plurality of memory cells further includes a third VSS line segment. The third VSS line segment is located in a second back metal layer that is disposed below the first back metal layer, extends along the second direction, and is electrically connected to the first VSS line segment and the second VSS line segment.

In accordance with some embodiments of the present disclosure, each of the plurality of memory cells further includes a first VDD line segment. The first VDD line segment is located in the first front metal layer, extends along the first direction, and is electrically connected to one of the source/drain regions of the first pull-up transistor and one of the source/drain regions of the second pull-up transistor.

In accordance with some embodiments of the present disclosure, each of the plurality of memory cells further includes a second VDD line segment. The second VDD line segment is located in the first back metal layer, extends along the first direction, and is electrically connected to the one of the source/drain regions of the first pull-up transistor and the one of the source/drain regions of the second pull-up transistor.

In accordance with some embodiments of the present disclosure, in a cell region of each of the plurality of memory cells, the additional front metal layer is free of any bit line segment, any write word line segment, any VDD line segment and any VSS line segment.

In accordance with some embodiments of the present disclosure, the additional front metal layer is a third front metal layer, and each of the plurality of memory cells further includes a second read word line segment that is located in a fourth front metal layer stacked on the third front metal layer, extends along the second direction, and is electrically connected to the first read word line segment.

In accordance with some embodiments of the present disclosure, the memory device further includes a plurality of bump pads. The plurality of bump pads are located in a bump pad layer that is disposed below the first back metal layer.

In accordance with some embodiments of the present disclosure, a memory device includes a plurality of memory cells which are arranged in a matrix that has a plurality of rows aligned in a first direction and a plurality of columns aligned in a second direction. Each of the plurality of memory cells includes a first pull-up transistor, a second pull-up transistor, a first pull-down transistor, a second pull-down transistor, a first pass-gate transistor, a second pass-gate transistor, a read pull-down transistor, a read pass-gate transistor, a non-inverting write bit line segment, an inverting write bit line segment, a read bit line segment, a first VDD line segment, a write word line segment, a read word line segment, a first VSS line segment and a second VSS line segment. The first pull-up transistor, the second pull-up transistor, the first pull-down transistor, the second pull-down transistor, the first pass-gate transistor, the second pass-gate transistor, the read pull-down transistor and the read pass-gate transistor are located in a transistor layer, and each include two source/drain regions. The non-inverting write bit line segment, the inverting write bit line segment, the read bit line segment and the first VDD line segment are located in a first front metal layer stacked on the transistor layer, and each extend along the first direction, where the first VDD line segment is electrically connected to one of the source/drain regions of the first pull-up transistor and one of the source/drain regions of the second pull-up transistor. The write word line segment is located in a second front metal layer stacked on the first front metal layer, and extends along the second direction. The read word line segment is located in an additional front metal layer stacked on the second front metal layer, and extends along the second direction. The first VSS line segment and the second VSS line segment are located in a first back metal layer disposed below the transistor layer, and each extend along the first direction, where the first VSS line segment is electrically connected to one of the source/drain regions of the first pull-down transistor, and the second VSS line segment is electrically connected to one of the source/drain regions of the second pull-down transistor and one of the source/drain regions of the read pull-down transistor. With respect to a first memory cell and a second memory cell of the plurality of memory cells that are adjacent to each other in the second direction, the one of the source/drain regions of the read pull-down transistor of the first memory cell and the one of the source/drain regions of the read pull-down transistor of the second memory cell are electrically connected to each other through a front contact that is located in an upper portion of the transistor layer, and that extends from a cell region of the first memory cell to a cell region of the second memory cell along the second direction.

In accordance with some embodiments of the present disclosure, each of the plurality of memory cells further includes a second VDD line segment. The second VDD line segment is located in the first back metal layer, extends along the first direction, and is electrically connected to the one of the source/drain regions of the first pull-up transistor and the one of the source/drain regions of the second pull-up transistor.

In accordance with some embodiments of the present disclosure, each of the plurality of memory cells further includes a third VSS line segment. The third VSS line segment is located in a second back metal layer disposed below the first back metal layer, extends along the second direction, and is electrically connected to the first VSS line segment and the second VSS line segment.

In accordance with some embodiments of the present disclosure, the one of the source/drain regions of the second pull-down transistor of the first memory cell and the one of the source/drain regions of the second pull-down transistor of the second memory cell are electrically connected to the one of the source/drain regions of the read pull-down transistor of the first memory cell and the one of the source/drain regions of the read pull-down transistor of the second memory cell through the front contact.

In accordance with some embodiments of the present disclosure, the additional front metal layer is one of a third front metal layer that is stacked on the second front metal layer and a fourth front metal layer that is stacked on the third front metal layer.

In accordance with some embodiments of the present disclosure, a memory device includes a plurality of memory cells which are arranged in a matrix that has a plurality of rows aligned in a first direction and a plurality of columns aligned in a second direction. Each of the plurality of memory cells includes a write port portion, a read port portion, a non-inverting write bit line segment, an inverting write bit line segment, a read bit line segment, a write word line segment, a read word line segment, a first VSS line segment and a second VSS line segment. The write port portion and the read port portion are located in a transistor layer, and each include a plurality of transistors. The non-inverting write bit line segment, the inverting write bit line segment and the read bit line segment are located in a first front metal layer stacked on the transistor layer, and each extend along the first direction, where the non-inverting write bit line segment and the inverting write bit line segment are electrically connected to the write port portion, and the read bit line segment is electrically connected to the read port portion. The write word line segment is located in a second front metal layer stacked on the first front metal layer, extends along the second direction, and is electrically connected to the write port portion. The read word line segment is located in an additional front metal layer stacked on the second front metal layer, extends along the second direction, and is electrically connected to the read port portion. The first VSS line segment and the second VSS line segment are located in a first back metal layer disposed below the transistor layer, and each extend along the first direction, where each of the first VSS line segment and the second VSS line segment is electrically connected to the write port portion. In a cell region of each of the plurality of memory cells, the additional front metal layer is free of any bit line segment, any write word line segment, any VDD line segment and any VSS line segment. With respect to a first memory cell and a second memory cell of the plurality of memory cells that are adjacent to each other in the second direction, the second VSS line segment of the first memory cell and the second VSS line segment of the second memory cell are electrically connected to each other through a front contact that is located in an upper portion of the transistor layer, and that extends from the cell region of the first memory cell to the cell region of the second memory cell along the second direction.

In accordance with some embodiments of the present disclosure, the second VSS line segment of the first memory cell is in contact with the second VSS line segment of the second memory cell.

In accordance with some embodiments of the present disclosure, with respect to each of the plurality of memory cells, the second VSS line segment is further electrically connected to the read port portion.

In accordance with some embodiments of the present disclosure, the memory device further includes a plurality of bump pads. The plurality of bump pads are located in a bump pad layer that is disposed below the first back metal layer.

In accordance with some embodiments of the present disclosure, each of the plurality of memory cells further includes a VDD line segment. The VDD line segment is located in the first front metal layer between the non-inverting write bit line segment and the inverting write bit line segment, and extends along the first direction.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device comprising:
a plurality of memory cells which are arranged in a matrix that has a plurality of rows aligned in a first direction and a plurality of columns aligned in a second direction, each of the plurality of memory cells including
a first pull-up transistor, a second pull-up transistor, a first pull-down transistor, a second pull-down transistor, a first pass-gate transistor, a second pass-gate transistor, a read pull-down transistor and a read pass-gate transistor which are located in a transistor layer, and each of which includes a gate electrode and two source/drain regions, where the first pull-up transistor, the second pull-up transistor, the first pull-down transistor and the second pull-down transistor cooperatively form a data latch for storing data, where when the first pass-gate transistor and the second pass-gate transistor conduct while the read pass-gate transistor does not conduct, a write operation is allowed to be performed on the data latch, and where when the read pass-gate transistor conducts while the first pass-gate transistor and the second pass-gate transistor do not conduct, a read operation is allowed to be performed on the data latch through the read pull-down transistor,
a non-inverting write bit line segment, an inverting write bit line segment and a read bit line segment which are located in a first front metal layer stacked on the transistor layer, and each of which extends along the first direction, where the non-inverting write bit line segment is electrically connected to one of the source/drain regions of the first pass-gate transistor, the inverting write bit line segment is electrically connected to one of the source/drain regions of the second pass-gate transistor, and the read bit line segment is electrically connected to one of the source/drain regions of the read pass-gate transistor,
a write word line segment which is located in a second front metal layer stacked on the first front metal layer, extends along the second direction, and is electrically connected to the gate electrode of the first pass-gate transistor and the gate electrode of the second pass-gate transistor,
a first read word line segment which is located in an additional front metal layer stacked on the second front metal layer, extends along the second direction, and is electrically connected to the gate electrode of the read pass-gate transistor,
a first VSS line segment and a second VSS line segment which are located in a first back metal layer disposed below the transistor layer, and each of which extends along the first direction, where the first VSS line segment is electrically connected to one of the source/drain regions of the first pull-down transistor, and the second VSS line segment is electrically connected to one of the source/drain regions of the second pull-down transistor;
with respect to a first memory cell and a second memory cell of the plurality of memory cells that are adjacent to each other in the second direction, the one of the source/drain regions of the second pull-down transistor of the first memory cell and the one of the source/drain regions of the second pull-down transistor of the second memory cell being electrically connected to each other through a front contact that is located in an upper portion of the transistor layer, and that extends from a cell region of the first memory cell to a cell region of the second memory cell along the second direction.

2. The memory device according to claim 1, wherein:
one of the source/drain regions of the read pull-down transistor of the first memory cell and one of the source/drain regions of the read pull-down transistor of the second memory cell are electrically connected to the one of the source/drain regions of the second pull-down transistor of the first memory cell and the one of the source/drain regions of the second pull-down transistor of the second memory cell through the front contact.

3. The memory device according to claim 1, wherein:
with respect to each of the plurality of memory cells, each of the first VSS line segment and the second VSS line segment is electrically connected to the one of the source/drain regions of a corresponding one of the first pull-down transistor and the second pull-down transistor through a back contact that is located in a back contact layer disposed between the transistor layer and the first back metal layer.

4. The memory device according to claim 1, wherein:
the second VSS line segment of the first memory cell is in contact with the second VSS line segment of the second memory cell.

5. The memory device according to claim 1, wherein each of the plurality of memory cells further includes:
a third VSS line segment located in a second back metal layer that is disposed below the first back metal layer, extending along the second direction, and electrically connected to the first VSS line segment and the second VSS line segment.

6. The memory device according to claim 1, wherein each of the plurality of memory cells further includes:
a first VDD line segment located in the first front metal layer, extending along the first direction, and electrically connected to one of the source/drain regions of the first pull-up transistor and one of the source/drain regions of the second pull-up transistor.

7. The memory device according to claim 6, wherein each of the plurality of memory cells further includes:
a second VDD line segment located in the first back metal layer, extending along the first direction, and electrically connected to the one of the source/drain regions of the first pull-up transistor and the one of the source/drain regions of the second pull-up transistor.

8. The memory device according to claim 1, wherein:
in a cell region of each of the plurality of memory cells, the additional front metal layer is free of any bit line segment, any write word line segment, any VDD line segment and any VSS line segment.

9. The memory device according to claim 1, wherein:
the additional front metal layer is a third front metal layer; and
each of the plurality of memory cells further includes a second read word line segment that is located in a fourth front metal layer stacked on the third front metal layer, extends along the second direction, and is electrically connected to the first read word line segment.

10. The memory device according to claim 1, further comprising:
a plurality of bump pads located in a bump pad layer that is disposed below the first back metal layer.

11. A memory device comprising:
a plurality of memory cells which are arranged in a matrix that has a plurality of rows aligned in a first direction and a plurality of columns aligned in a second direction, each of the plurality of memory cells including
a first pull-up transistor, a second pull-up transistor, a first pull-down transistor, a second pull-down transistor, a first pass-gate transistor, a second pass-gate transistor, a read pull-down transistor and a read pass-gate transistor which are located in a transistor layer, and each of which includes two source/drain regions,
a non-inverting write bit line segment, an inverting write bit line segment, a read bit line segment and a first VDD line segment which are located in a first front metal layer stacked on the transistor layer, and each of which extends along the first direction, where the first VDD line segment is electrically connected to one of the source/drain regions of the first pull-up transistor and one of the source/drain regions of the second pull-up transistor,
a write word line segment which is located in a second front metal layer stacked on the first front metal layer, and extends along the second direction,
a read word line segment which is located in an additional front metal layer stacked on the second front metal layer, and extends along the second direction,
a first VSS line segment and a second VSS line segment which are located in a first back metal layer disposed below the transistor layer, and each of which extends along the first direction, where the first VSS line segment is electrically connected to one of the source/drain regions of the first pull-down transistor, and the second VSS line segment is electrically connected to one of the source/drain regions of the second pull-down transistor and one of the source/drain regions of the read pull-down transistor;
with respect to a first memory cell and a second memory cell of the plurality of memory cells that are adjacent to each other in the second direction, the one of the source/drain regions of the read pull-down transistor of the first memory cell and the one of the source/drain regions of the read pull-down transistor of the second memory cell being electrically connected to each other through a front contact that is located in an upper portion of the transistor layer, and that extends from a cell region of the first memory cell to a cell region of the second memory cell along the second direction.

12. The memory device according to claim 11, wherein each of the plurality of memory cells further includes:
a second VDD line segment located in the first back metal layer, extending along the first direction, and electrically connected to the one of the source/drain regions of the first pull-up transistor and the one of the source/drain regions of the second pull-up transistor.

13. The memory device according to claim 11, wherein each of the plurality of memory cells further includes:
a third VSS line segment located in a second back metal layer that is disposed below the first back metal layer, extending along the second direction, and electrically connected to the first VSS line segment and the second VSS line segment.

14. The memory device according to claim 11, wherein:
the one of the source/drain regions of the second pull-down transistor of the first memory cell and the one of the source/drain regions of the second pull-down transistor of the second memory cell are electrically connected to the one of the source/drain regions of the read pull-down transistor of the first memory cell and the one of the source/drain regions of the read pull-down transistor of the second memory cell through the front contact.

15. The memory device according to claim 11, wherein:
the additional front metal layer is one of a third front metal layer that is stacked on the second front metal layer and a fourth front metal layer that is stacked on the third front metal layer.

16. A memory device comprising:
a plurality of memory cells which are arranged in a matrix that has a plurality of rows aligned in a first direction and a plurality of columns aligned in a second direction, each of the plurality of memory cells including
a write port portion and a read port portion which are located in a transistor layer, and each of which includes a plurality of transistors,
a non-inverting write bit line segment, an inverting write bit line segment and a read bit line segment which are located in a first front metal layer stacked on the transistor layer, and each of which extends along the first direction, where the non-inverting write bit line segment and the inverting write bit line segment are electrically connected to the write port portion, and the read bit line segment is electrically connected to the read port portion,
a write word line segment which is located in a second front metal layer stacked on the first front metal layer, extends along the second direction, and is electrically connected to the write port portion,
a read word line segment which is located in an additional front metal layer stacked on the second front metal layer, extends along the second direction, and is electrically connected to the read port portion, and
a first VSS line segment and a second VSS line segment which are located in a first back metal layer disposed below the transistor layer, and each of which extends along the first direction, where each of the first VSS line segment and the second VSS line segment is electrically connected to the write port portion;
in a cell region of each of the plurality of memory cells, the additional front metal layer is free of any bit line segment, any write word line segment, any VDD line segment and any VSS line segment;
with respect to a first memory cell and a second memory cell of the plurality of memory cells that are adjacent to each other in the second direction, the second VSS line segment of the first memory cell and the second VSS line segment of the second memory cell being electrically connected to each other through a front contact that is located in an upper portion of the transistor layer, and that extends from the cell region of the first memory cell to the cell region of the second memory cell along the second direction.

17. The memory device according to claim 16, wherein:
the second VSS line segment of the first memory cell is in contact with the second VSS line segment of the second memory cell.

18. The memory device according to claim 16, wherein:
with respect to each of the plurality of memory cells, the second VSS line segment is further electrically connected to the read port portion.

19. The memory device according to claim 16, further comprising:
a plurality of bump pads located in a bump pad layer that is disposed below the first back metal layer.

20. The memory device according to claim 16, wherein each of the plurality of memory cells further includes:
a VDD line segment located in the first front metal layer between the non-inverting write bit line segment and the inverting write bit line segment, and extending along the first direction.
